(19) United States
(12) Patent Application Publication
(10) Pub. No.: US 2017/0008146 A1
(43) Pub. Date: Jan. 12, 2017

(54) CHEMICAL MECHANICAL PLANARIZATION CONDITIONER

(71) Applicants: Mark Kevin Diaz, Chandler, AZ (US); Mark Bubnick, Lewis Center, OH (US); Thomas S. Namola, Columbus, OH (US)

(72) Inventors: Mark Kevin Diaz, Chandler, AZ (US); Mark Bubnick, Lewis Center, OH (US); Thomas S. Namola, Columbus, OH (US)

(73) Assignee: Abrasive Technology, Inc., Lewis Center, OH (US)

(21) Appl. No.: 15/193,604

(22) Filed: Jun. 27, 2016

Related U.S. Application Data
(60) Provisional application No. 62/190,914, filed on Jul. 10, 2015.

(51) Int. Cl. B24B 53/017; H01L 21/306; B24B 37/10

(52) U.S. Cl. CPC B24B 53/017; B24B 37/105; H01L 21/30625

(57) ABSTRACT

A device and method of breaking in a chemical mechanical planarization (CMP) polishing pad using multiple pad conditioners to break-in and maintain a condition of the polishing pad.

### CROSS-REFERENCE TO RELATED APPLICATIONS

This application claims the benefit of U.S. Provisional Patent Application Ser. No. 62/190,914 entitled “CHEMICAL MECHANICAL PLANARIZATION CONDITIONER” filed on Jul. 10, 2015. The entirety of the above-noted application is incorporated by reference herein.

### ORIGIN

The innovation disclosed herein relates to Chemical Mechanical Planarization (CMP) and more specifically, to a CMP conditioning device.

### BACKGROUND

In current Chemical Mechanical Planarization (CMP) practices, CMP polishing pads are broken in with the same conditioning device (conditioning block, ring, end effector, plate, disk, etc.) used to sustain the desired CMP polishing pad surface conditions during the CMP process. More specifically, current CMP practice utilizes a single pad conditioner that has an abrasive surface (e.g., diamond, silicon carbide, ceramic material etc.) bonded to a substrate (e.g., metal, plastic, ceramic, etc.) to break-in a new CMP polishing pad and to maintain the polishing pad surface condition suitable for the CMP process to effectively and efficiently perform consistently with respect to a surface finish, removal rate, and uniformity of the materials being targeted for polishing throughout the lifetime of the CMP polishing pad. Using one pad conditioner to break in a CMP polishing pad and during the process period to maintain the condition of the pad during polishing often results in inconsistent and extended initial CMP polishing pad break in times (e.g., 30 minutes or greater). Another disadvantage is that failure to effectively break in the new CMP polishing pad does occur in some cases. In addition, it is typical that the CMP pad conditioner has a greater life span than the life span of one CMP polishing pad. Thus, subsequent CMP polishing pads are sometimes broken in with a partially worn CMP pad conditioner, which can lead to an increase in process variation and instability.

### SUMMARY

The following presents a simplified summary in order to provide a basic understanding of some aspects of the innovation. This summary is not an extensive overview of the innovation. It is not intended to identify key/critical elements or to delineate the scope of the innovation. Its sole purpose is to present some concepts of the innovation in a simplified form as a prelude to the more detailed description that is presented later.

In an aspect of the innovation, conditioning block, ring, end effector, or conditioning disk (ring, plate, etc.) apparatus and process is disclosed that is used to perform the initial break in of a CMP polishing pad. The innovation utilizes physical abrasive characteristics specific to the CMP pad material and CMP process in which it is intended to operate in. This will enable the new CMP pad to more readily accept the traditional CMP process conditioner after using the initial/new CMP break in conditioner to sustain the desired process throughout the CMP polishing pad life.

In another aspect of the innovation, a system of conditioning a chemical mechanical planarization (CMP) polishing pad is disclosed that includes a first pad conditioner pad including an abrasive portion having first abrasive properties, wherein the first pad conditioner breaks-in the polishing pad for a predetermined break-in period, a second pad conditioner including an abrasive portion having second abrasive properties, wherein the second pad conditioner maintains a condition of the polishing pad after the break-in period, wherein the first abrasive properties are different than the second abrasive properties.

In another aspect of the innovation, a method of performing a chemical mechanical planarization (CMP) is disclosed that includes providing a polishing pad, mounting a break-in pad conditioner on a CMP tool, wherein the break-in pad conditioner includes an abrasive portion having first abrasive properties that interacts with the polishing pad to break-in the polishing pad, breaking in the polishing pad on the CMP tool for a predetermined period of time, removing the break-in pad conditioner from the CMP tool, mounting a process pad conditioner on the CMP tool, wherein the process pad conditioner includes an abrasive portion having second abrasive properties that are different from the first abrasive properties that interacts with the polishing pad to maintain a condition of the polishing pad, and polishing a wafer.

To accomplish the foregoing and related ends, certain illustrative aspects of the innovation are described herein in connection with the following description and the annexed drawings. These aspects are indicative, however, of but a few of the various ways in which the principles of the innovation can be employed and the subject innovation is intended to include all such aspects and their equivalents. Other advantages and novel features of the innovation will become apparent from the following detailed description of the innovation when considered in conjunction with the drawings.

### BRIEF DESCRIPTION OF THE DRAWINGS

FIG. 1 is a block diagram illustration of a chemical mechanical planarization (CMP) system in accordance with an aspect of the innovation.

FIGS. 2 and 3 are front and top views respectively of the CMP system in accordance with the innovation.

FIG. 4 is a perspective front view of one example embodiment of the innovative CMP pad conditioner that may be used as a break-in or process conditioner in accordance with an aspect of the innovation.

FIG. 5 is a rear view of the example embodiment of the innovative CMP pad conditioner shown in FIG. 4 in accordance with an aspect of the innovation.

FIG. 6 is a front view of another example embodiment of the innovative CMP pad conditioner that may be used as a break-in or process conditioner in accordance with an aspect of the innovation.

FIG. 7 is a block diagram describing a method of breaking in a CMP polishing pad using the innovative CMP pad conditioner in accordance with an aspect of the innovation.

### DETAILED DESCRIPTION

The innovation is now described with reference to the drawings, wherein like reference numerals are used to refer to like elements throughout. In the following description, for purposes of explanation, numerous specific details are set forth in order to provide a thorough understanding of the subject innovation. It may be evident, however, that the innovation can be practiced without these specific details. In other instances, well-known structures and devices are shown in block diagram form in order to facilitate describing the innovation.

While specific characteristics are described herein (e.g., thickness), it is to be understood that the features, functions and benefits of the innovation can employ characteristics that vary from those described herein. These alternatives are to be included within the scope of the innovation and claims appended hereto.

While, for purposes of simplicity of explanation, the one or more methodologies shown herein, e.g., in the form of a flow chart, are shown and described as a series of acts, it is to be understood and appreciated that the subject innovation is not limited by the order of acts, as some acts may, in accordance with the innovation, occur in a different order and/or concurrently with other acts from that shown and described herein. For example, those skilled in the art will understand and appreciate that a methodology could alternatively be represented as a series of interrelated states or events, such as in a state diagram. Moreover, not all illustrated acts may be required to implement a methodology in accordance with the innovation.

Disclosed herein is an innovative device and process to condition a new Chemical Mechanical Planarization (CMP) polishing pad or refurbish a used CMP polishing pad that has been idle for a period of time for use in integrated circuit device (e.g., semiconductors, memory, solar, glass silicon, etc.) polishing processes in accordance with an aspect of the innovation. CMP is a polishing process, which utilizes a chemical slurry formulation and mechanical polishing process to remove unwanted conductive or dielectric materials on the silicon wafer, achieving a near-perfect flat and smooth surface upon which layers of integrated circuitry are built. The device and process includes an innovative break-in CMP pad conditioner that includes a break-in a polishing pad and a separate process pad conditioner used during the wafer polishing process to maintain the polishing pad in a proper condition that overcomes the above mentioned disadvantages associated with conventional methods.

After the polishing pad break-in period, a CMP process pad conditioner is used during a CMP wafer polishing process. More specifically, the innovation utilizes a CMP pad conditioner assembly that may include a conditioning block, ring, end effector or conditioning disk (ring, plate etc.) used to break-in the CMP polishing pad and also used during the wafer polishing process to keep the polishing pad conditioned. The innovation utilizes physical abrasive characteristics specific to the CMP polishing pad material and CMP polishing process in which it is intended to operate. This enables the CMP polishing pad to more readily accept the CMP process conditioner after using the innovative initial/new break-in CMP pad conditioner to sustain the desire process throughout the CMP polishing pad life.

Thus, the innovation includes a first (break-in) CMP pad conditioner used during an initial CMP polishing pad break-in for a new CMP polishing pad or may be used to refresh an existing CMP polishing pad that has not been used for an extended period of time. Once the CMP polishing pad is broken in a second (process) CMP pad conditioner is used during the CMP wafer polishing process. An aggressiveness of the abrasive properties of the break-in CMP conditioner can be less than or greater than an aggressiveness of the in process CMP conditioner. Aggressiveness is determined by the size, shape and protrusion of the abrasive material used on the CMP pad conditioner. Aggressiveness is further defined by a pad cut rate, which is the amount of CMP pad thickness removed due to the aggressiveness of the CMP pad conditioner. In addition, CMP pad asperity can be increased/decreased by increasing or reducing the pad surface roughness. Further, based on the aggressiveness of the CMP conditioner, the CMP pad can be revitalized, refreshed and/or cleaned of wear, residual slurry or polishing residue. These physical attributes are determined by the CMP pad type, CMP pad material, CMP process requirements, and CMP tool configuration.

In one example embodiment, aggressive may refer to an amount of time of the break-in period. Thus, in this example, the break-in conditioner is capable of breaking down and removing an outer layer of the polishing pad in less time than the process conditioner. For example, in some cases depending on the material of the polishing pad, the innovative CMP break-in conditioner may decrease the break-in period of the polishing pad from approximately 15% to greater than 50% based on application requirements.

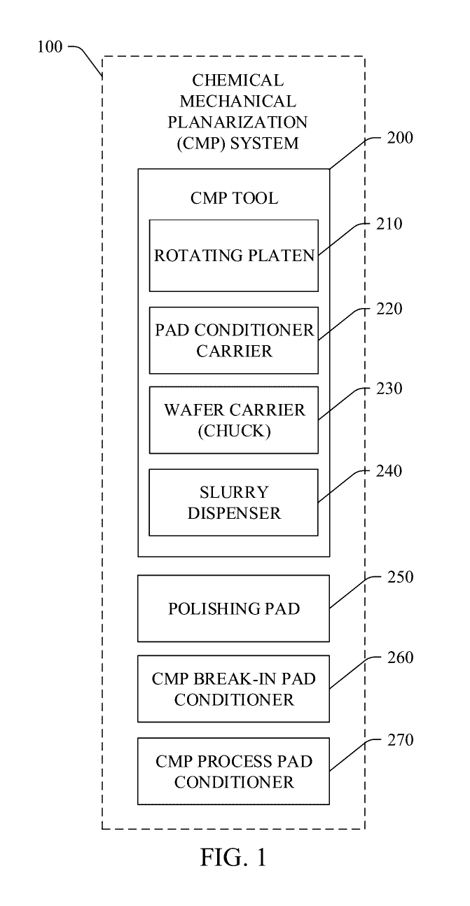

Referring now to the figures, FIGS. 1-3 represent a block diagram illustration, a top view and a front view respectively of an example CMP system 100 in accordance with an aspect of the innovation. The CMP system 100 includes an example CMP tool 200 used to polish wafers for use in integrated circuit devices (e.g., semiconductors, memory, solar, glass silicon, etc.), a polishing pad 250, a CMP break-in pad conditioner (first conditioner) 260, and a CMP process (or in-process) pad conditioner (second conditioner) 270.

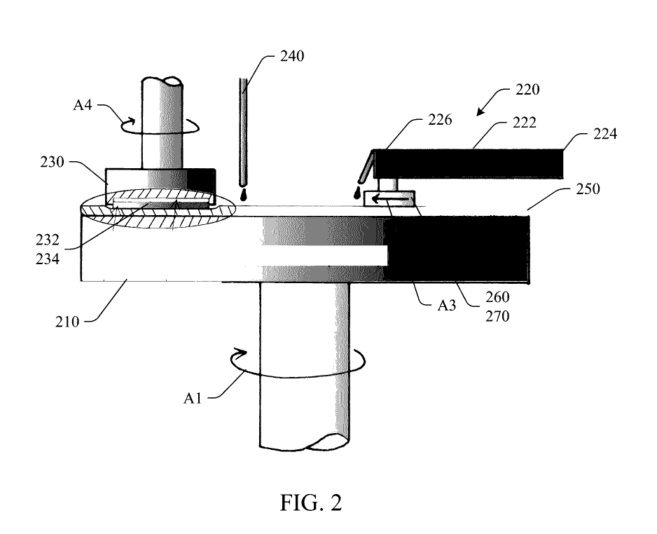

The CMP tool 200 illustrated in FIGS. 2 and 3 is but one example embodiment of a CMP tool 200 for use in polishing integrated circuit devices that can utilize the innovative system and process disclosed herein. The CMP tool 200 includes a rotating platen 210, a movable pad conditioner carrier 220, a wafer carrier 230, and a slurry dispenser 240. In the example embodiment, the rotating platen 210 has a circular shape and includes a top surface that supports a polishing pad 250. In this embodiment, during the polishing process, the rotating platen 210 rotates in a clockwise direction (counterclockwise in alternate embodiments) as indicated by the arrow A1.

The movable pad conditioner carrier 220 includes an arm 222 that pivots at a first (proximate) end 224 and provides a connection device at a distal end 226 that allows a connection of the pad conditioners 260, 270 to the movable pad conditioner carrier 220. In this embodiment, during the break-in and/or polishing process, the arm 222 moves across the polishing pad 250 as indicated by the arrow A2. In this embodiment, the pad conditioner 260, 270 rotates in a clockwise direction (counterclockwise in alternate embodiments) as indicated by the arrow A3.

The wafer carrier 230 holds a blanket wafer 232 for use in the break-in conditioning process and an integrated circuit wafer 234 for use in integrated circuit devices (e.g., semiconductors, memory, solar, glass silicon, etc.) that is polished by the polishing pad 250. During the polishing pad break-in period, the blanket wafer 232 may be changed every 1-3 minutes. Thus, anywhere from 15-30 blanket wafers 232 may be used during a polishing pad break-in. As the blanket wafers 232 are rather expensive, the process of breaking in a polishing pad can be quite expensive. As will be seen further below, the innovative system and process decreases the amount of blanket wafers 234 required to break-in the polishing pad 250, thus, saving manufacturing costs. The wafer carrier 230 also rotates in a clockwise direction (counterclockwise in alternate embodiments) as indicated by the arrow A5. In addition, the wafer carrier 230 also moves across the polishing pad 250 in a back and forth motion as indicated by the arrows A5.

As the CMP tool 200 is generally known in the art, additional details regarding the operation of the CMP tool will not be described. In addition, there are many variations of a CMP tool. For example the rotating platen, movable pad conditioner carrier, and the wafer carrier may rotate in an opposite (e.g., counterclockwise) direction. Thus, the example CMP tool described above and illustrated in the figures is for illustration purposes only and is not intended to limit the scope of the innovation.

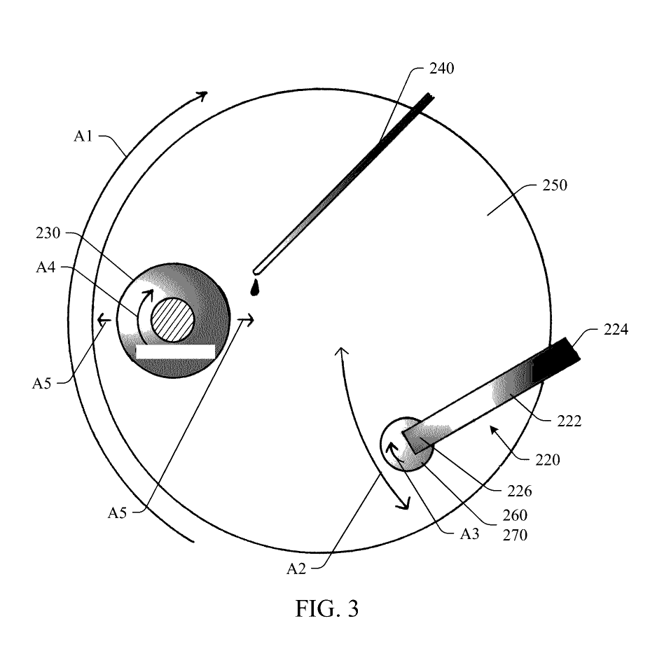

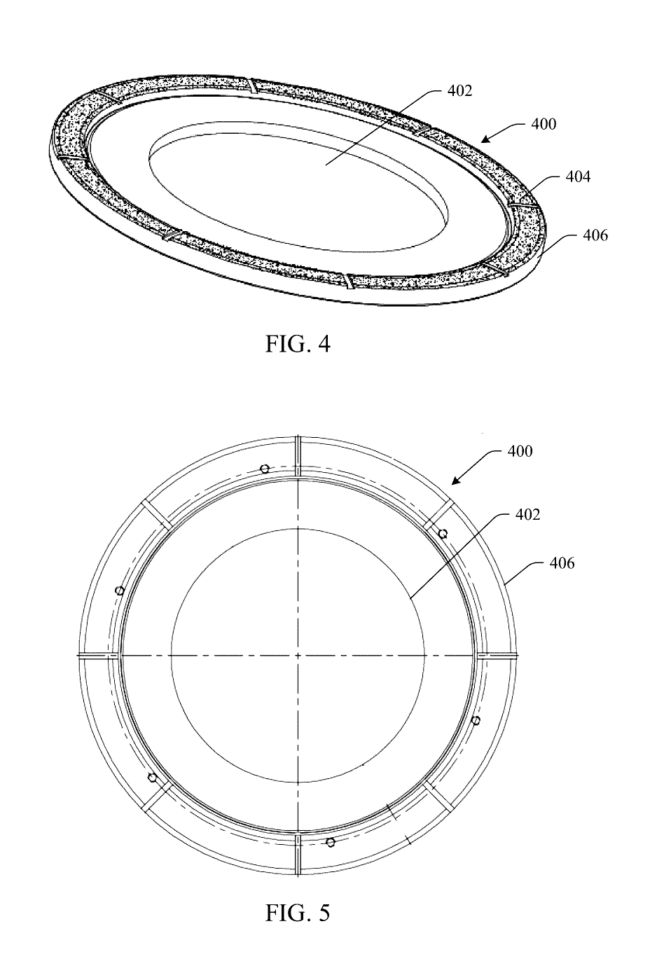

FIG. 4 is a perspective front view and FIG. 5 is a rear view of one example embodiment of a CMP pad conditioner 400 that may be used as a CMP break-in pad conditioner 260 or as a CMP process pad conditioner 270 in accordance with an aspect of the innovation. In this example embodiment, the CMP pad conditioner 400 is a ring type pad conditioner having an opening 402 defined in a center thereof. An abrasive (or polishing) portion 404 disposed on an outer perimeter 406 of the pad conditioner 400.

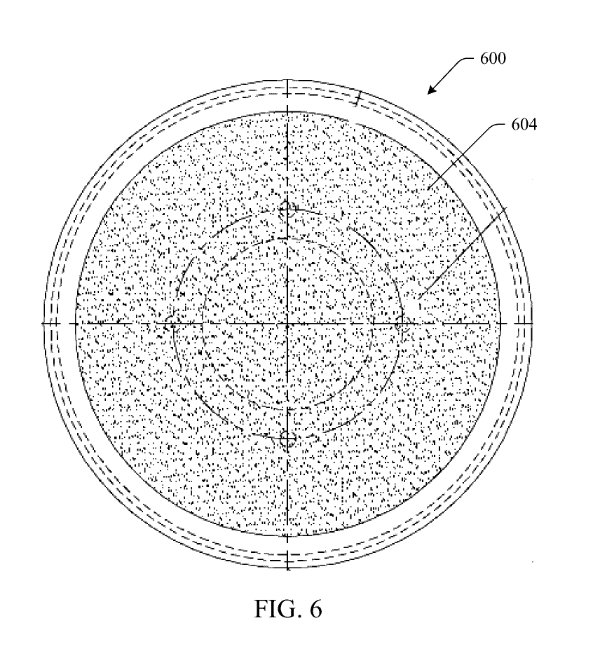

FIG. 6 is a front view of another example embodiment of a CMP pad conditioner 600 that may be used as a CMP break-in pad conditioner 260 or as a CMP process pad conditioner 270 in accordance with an aspect of the innovation. The CMP pad conditioner 600 is a disk type pad conditioner that includes an engineered abrasive (or polishing) portion 604.

The CMP pad conditioner can be a “single-sided” conditioning ring, disk, etc. or a “double-sided” conditioning ring or disk such that a first side of includes the break-in conditioning specifications and a second side includes the process conditioning specifications. The CMP pad conditioner interacts with the CMP pad in such a manner as to refresh or maintain a pad surface condition suitable for the CMP process to effectively and efficiently perform in a consistent manner with respect to surface finish, removal rate and uniformity of the materials being targeted for polishing.

The CMP pad conditioner uses an abrasive, such as but not limited to a diamond, CVD diamond or any other deposited abrasive materials, ceramic material, silicon carbide materials, raised, machined or molded metal or ceramic surface coated or treated with a chemically or wear resistant material, etc. that is bonded or integrated onto a metallic or non-metallic (e.g., plastic, ceramic, etc.) substrate. The abrasive protrudes from a surface of the substrate thereby providing an abrasive interface between the CMP pad conditioner and the CMP polishing pad. The abrasive may have varying degrees of abrasive particle size, shape, grade, and concentration (e.g., weight, surface area, etc.). The abrasive may have single or combinations of abrasive type, shape, size, grade and concentration and can be patterned or random in placement on the surface of the pad conditioner.

As such, the abrasive disposed on the CMP break-in pad conditioner 260 may have a different abrasive particle size, shape, grade, and concentration (e.g., weight, surface area, etc.) than the abrasive disposed on the CMP process pad conditioner 270. For example, the abrasive properties of the abrasive on the CMP break-in pad conditioner 260 may have a larger particle size and may be analogous to a heavier grit sandpaper (e.g., 80 grit), which is more suited to break-in the polishing pad 250. This in turn reduces the break-in period by approximately 15-50%. Whereas, the abrasive properties of the abrasive on the CMP process pad conditioner 270 may have a smaller particle size and may be analogous to a finer grit sandpaper (e.g., 220 grit), which is more suited to maintain a condition of the polishing pad 250 during the wafer polishing process.

Referring to Table 1 below, in multiple tests performed by an independent party, results indicate that the polishing pad 250 break-in period is reduced by approximately 35%. The data in Table 1 is normalized, which means that the data under the “Original System/Method” has been normalized to 1.0. The data under the “Innovative System/Method” then represents a difference from the normalized data.

Thus, in relation to break-in time, the innovative system/method improved the break-in time by 70% in eight tests, 50% in two tests, and 35% in two tests. In relation to the number of wafer blankets used, the number decreased by as little as 30% to as much as 70%. In relation to the polishing pad lifetime, the lifetime of the polishing pad increased by 20% in three of the tests, by 25% in one of the tests, and remained the same in the remaining eight tests. The test results clearly demonstrate the improvement the innovative pad conditioners have over the original system/method.

TABLE 1

| | Original | | | | | |
|---|---|---|---|---|---|---|
| | System/Method | | | Innovative System/Method | | |
| | Break In | No. of Blanket | Pad | Break In | No. of Blanket | Pad |
| Test # | Time | Wafers used | Lifetime | Time | Wafers used | Lifetime |
| 1 | 1.0 | 1.0 | 1.0 | 0.65 | 0.70 | 1.25 |
| 2 | 1.0 | 1.0 | 1.0 | 0.65 | 0.50 | 1.00 |
| 3 | 1.0 | 1.0 | 1.0 | 0.50 | 0.50 | 1.00 |
| 4 | 1.0 | 1.0 | 1.0 | 0.30 | 0.50 | 1.00 |
| 5 | 1.0 | 1.0 | 1.0 | 0.30 | 0.25 | 1.20 |
| 6 | 1.0 | 1.0 | 1.0 | 0.30 | 0.25 | 1.20 |
| 7 | 1.0 | 1.0 | 1.0 | 0.30 | 0.25 | 1.20 |
| 8 | 1.0 | 1.0 | 1.0 | 0.30 | 0.25 | 1.00 |
| 9 | 1.0 | 1.0 | 1.0 | 0.30 | 0.30 | 1.00 |
| 10 | 1.0 | 1.0 | 1.0 | 0.30 | 0.30 | 1.00 |
| 11 | 1.0 | 1.0 | 1.0 | 0.50 | 0.50 | 1.00 |
| 12 | 1.0 | 1.0 | 1.0 | 0.30 | 0.50 | 1.00 |

This system of multiple pad conditioners has several advantages. First, the polishing pad material differences (urethane, thermoset plastic, thermoplastic, woven materials, porous and non-porous materials) may require different conditioning properties to perform initial pad break in vs in-situ or ex-situ process conditioning. The differences in the polishing pad properties (e.g., hardness, porosity, compressibility, single pad or pad stack, individually formed casted, molded, injected, pressed or poured, sheet or cake process) may also require different conditioning properties to perform the initial pad break-in. In addition, there are different polishing pad characteristics within the same pad type (including but not limited to hardness, porosity, compressibility, or multiple pad type materials within the same CMP polishing pad).

The initial break-in of the polishing pad and maintaining the condition of the polishing pad during the polishing process are different. Polishing pad break-in is typically longer in duration and can be done using either slurry or DIW, can utilize higher or lower downforces, conditioner or platen rotation (rpm) than “typical” or process conditioning recipes for CMP conditioning. The innovative break-in conditioner shortens the break-in process, as described above. In addition, soft pad technology is gaining momentum and conditioning of these types of pads could require break-in conditioning different between actual conditioner and initial pad break in requirements.

Still further, another advantage is that efficiency is improved by separating the break-in process and the in-situ and ex-situ conditioning (e.g., maintain the condition of the CMP polishing pad). In other words, the efficiency of the initial pad break in process is improved by utilizing a CMP break-in pad conditioner 260 more suited to perform the initial polishing pad break in process. As a result, the break-in period of the polishing pad 250 is reduced by approximately 15-50%, which results in an overall improvement in the CMP process conditioner performance, stability and lifetime.

The innovative CMP conditioner can be used in any CMP process application that utilizes CMP polishing pads and requires CMP polishing conditioners or that could utilize CMP polishing pads and conditioning. For example, CMP processes practiced in semiconductor, memory, solar, silicon and glass polishing processes. Also, CMP processes including but not limited to, oxide CMP, ILD, STI (direct and indirect STI), Copper CMP (1^{st}, 2^{nd} and 3^{rd} step Cu CMP), Tungsten CMP, and Aluminum CMP.

The innovation can be used on any commercially available CMP tool and/or in conjunction with the use of CMP pads. Any company, entity, organization using CMP as part of their product manufacturing process. For example, any Integrated Circuit (IC) manufacturer, memory manufacturer (MEMS) can utilize the disclosed innovation. The advantages for using this product would be to improve tool utilization (less CMP polishing pad break in failures, shorten new CMP polishing pad break in periods, improve process efficiency, and in some cases yield.

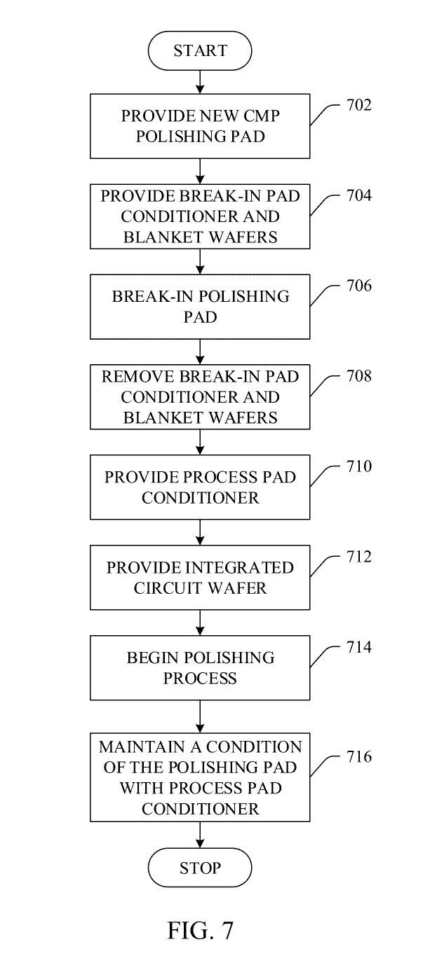

Referring to FIG. 7, a method of polishing a wafer that includes breaking in CMP polishing pad (or alternately refurbishing a used CMP polishing pad) will be described. At 702, a new CMP polishing pad is provided. At 704, a break-in conditioner is provided and mounted to the distal end 226 of the movable pad conditioner carrier 220. Simultaneously, at 704, a blanket wafer 232 is attached to the wafer carrier 230. At 706, the break-in conditioner breaks in the CMP polishing pad 250 on the CMP tool 200 similar to the example embodiment shown in FIGS. 2 and 3 for a period of time determined upon the CMP polishing pad type, material, and process requirements. Specifically, the break-in conditioner prepares the CMP polishing pad surface to more readily accept the CMP process pad conditioner 270. At 708, the CMP break-in pad conditioner 260 and the blanker wafer 232 are removed. At 710, the CMP process pad conditioner 270 is mounted to the distal end 226 of the movable pad conditioner carrier 220. At 712, the integrated circuit wafer 234 is mounted to the wafer carrier 230. At 714, the polishing process to the integrated circuit wafer 234 is started. At 716, the condition of the polishing pad 250 is maintained with the CMP process pad conditioner 270 during the polishing of the integrated circuit wafer 234.

What has been described above includes examples of the innovation. It is, of course, not possible to describe every conceivable combination of components or methodologies for purposes of describing the subject innovation, but one of ordinary skill in the art may recognize that many further combinations and permutations of the innovation are possible. Accordingly, the innovation is intended to embrace all such alterations, modifications and variations that fall within the spirit and scope of the appended claims. Furthermore, to the extent that the term “includes” is used in either the detailed description or the claims, such term is intended to be inclusive in a manner similar to the term “comprising” as “comprising” is interpreted when employed as a transitional word in a claim.

What is claimed is:

1. A system of conditioning a chemical mechanical planarization (CMP) polishing pad comprising:
a first pad conditioner including an abrasive portion having first abrasive properties, wherein the first pad conditioner breaks-in the polishing pad for a predetermined break-in period;
a second pad conditioner including an abrasive portion having second abrasive properties, wherein the second pad conditioner maintains a condition of the polishing pad after the break-in period,
wherein the first abrasive properties are different than the second abrasive properties.

2. The system of claim 1, wherein the first abrasive properties facilitate breaking in the polishing pad and the second abrasive properties facilitate maintaining a condition of the polishing pad.

3. The system of claim 1, wherein the first abrasive properties have an aggressiveness that is greater than an aggressiveness of the second abrasive properties.

4. The system of claim 3, wherein the first abrasive properties facilitate reducing the predetermined break-in period by approximately 15-50%.

5. The system of claim 1, wherein the abrasive properties of the first pad conditioner have a hardness that is greater than the abrasive properties of the second pad conditioner.

6. The system of claim 1, wherein based on the application, the first abrasive properties of the first pad conditioner has an aggressiveness that can be less than or greater than an aggressiveness of the second abrasive properties of the second pad conditioner.

7. The system of claim 1, wherein the polishing pad may be new or may be a used polishing pad that has been idle for a period of time and the breaking in of the new or used polishing pad on the CMP tool reduces a time required to prepare a surface of the polishing pad to more readily accept the process pad conditioner.

8. A method of performing a chemical mechanical planarization (CMP) comprising:
providing a polishing pad;
mounting a break-in pad conditioner on a CMP tool, wherein the break-in pad conditioner includes an abrasive portion having first abrasive properties that interacts with the polishing pad to break-in the polishing pad;
breaking in the polishing pad on the CMP tool for a predetermined period of time;
removing the break-in pad conditioner from the CMP tool;
mounting a process pad conditioner on the CMP tool, wherein the process pad conditioner includes an abrasive portion having second abrasive properties that are different from the first abrasive properties that interacts with the polishing pad to maintain a condition of the polishing pad; and
polishing a wafer.

9. The method of claim 8, wherein breaking in the polishing pad is reduced from as little as 15% to as much as 50% depending on the polishing pad type material and process requirements.

10. The method of claim 8, wherein based on the application, the first abrasive properties of the break-in pad conditioner has an aggressiveness that can be less than or greater than an aggressiveness of the second abrasive properties of the process pad conditioner.

11. The method of claim 8, wherein the polishing pad may be new or may be a used polishing pad that has been idle for a period of time and the breaking in of the new or used polishing pad on the CMP tool reduces a time required to prepare a surface of the polishing pad to more readily accept the process pad conditioner.

12. The method of claim 8, wherein the break-in pad conditioner and the process pad conditioner are ring type pad conditioners.

13. The method of claim 8, wherein the break-in pad conditioner and the process pad conditioner are disk type pad conditioners.

14. A system of polishing a wafer for use in integrated circuits comprising:
a polishing pad;
a break-in pad conditioner including an abrasive portion having first abrasive properties;
an in-process pad conditioner including an abrasive portion having second abrasive properties,
wherein the first abrasive properties are different than the second abrasive properties.

15. The system of claim 14, wherein the first abrasive properties facilitate breaking in the polishing pad and the second abrasive properties facilitate maintaining a condition of the polishing pad.

16. The system of claim 14, wherein the first abrasive properties have an aggressiveness that is greater than an aggressiveness of the second abrasive properties.

17. The system of claim 16, wherein the first abrasive properties facilitate reducing the predetermined break-in period by approximately 15-50%.

18. The system of claim 14, wherein the abrasive properties of the break-in pad conditioner have a hardness that is greater than the abrasive properties of the in-process pad conditioner.

19. The system of claim 14, wherein based on the application, the first abrasive properties of the break-in pad conditioner has an aggressiveness that can be less than or greater than an aggressiveness of the in-process abrasive properties of the second pad conditioner.

20. The system of claim 14, wherein the polishing pad may be new or may be a used polishing pad that has been idle for a period of time and the breaking in of the new or used polishing pad on the CMP tool reduces a time required to prepare a surface of the polishing pad to more readily accept the in-process pad conditioner.
